(19) United States
(12) Patent Application Publication
(10) Pub. No.: US 2014/0197844 A1
(43) Pub. Date: Jul. 17, 2014

(54) ACTIVE CONTINUOUS DC POWER SUPPLY INSULATION MALFUNCTION DETECTION CIRCUIT

(71) Applicant: Kuo-Ching Chang, Kaohsiung (TW)

(72) Inventor: Kuo-Ching Chang, Kaohsiung (TW)

(21) Appl. No.: 14/151,630

(22) Filed: Jan. 9, 2014

(30) Foreign Application Priority Data
Jan. 14, 2013 (TW) 102101314

(51) Int. Cl. G01R 31/02

(52) U.S. Cl. CPC G01R 31/025
USPC 324/509

(57) ABSTRACT

An active continuous DC power supply insulation malfunction detection circuit includes a leakage current detection unit, a positive voltage terminal compensation unit and a negative voltage terminal compensation unit respectively at a positive voltage terminal and a negative voltage terminal of the power supply system. The positive and negative voltage terminal compensation units include respectively a one-way discharger and a power source unit that are forward conducted. The invention can improve the shortcoming of the conventional detection techniques that use passive elements for detecting ground insulation deterioration by letting the power source unit discharge through the one-way discharger so that the leakage current detection unit can continuously detect and measure current variations passing through the positive and negative voltage terminals without interruption, and thereby easily obtain leakage current value and provide active and continuous detection of ground insulation deterioration.

### FIELD OF THE INVENTION

The present invention relates to a DC power supply insulation malfunction detection circuit and particularly to a detection circuit capable of continuously monitoring loop leakage current when being grounded during power supply of a DC system.

### BACKGROUND OF THE INVENTION

A DC power supply system generally comprises a storage battery set, a charger and a power converter to provide high quality DC power to important loads. In order to improve the quality of the DC power supply system, it generally adopts a non-grounding system. Namely, positive bus and negative bus have desirable insulation against ground. In the event that the system has malfunction of a single spot to ground, DC operation is not affected. However, in the event that two or more than two spots have ground malfunction that causes short circuit of the bus bar at the positive and negative voltage terminals, the total DC system could break down.

Please refer to FIG. 1 for a conventional malfunction detection circuit for DC system branch ground. Assuming that one of the loops of a power supply system 1 has ground malfunction at the positive voltage terminal, insulation resistor R_{f} and grounding resistor R form a loop and ground leakage current. Through a leakage current detector T, the ground malfunction happens to the Nth loop can be determined easily. While detecting the leakage current is quite easy, the positive and negative voltage terminals have to be coupled respectively with the grounding resistor R, this compromises the original insulation characteristic. An improved alternative is to connect the grounding resistor R with a switch in series (not shown in the drawings). Such an approach provides non-grounding power supply and can maintain desired insulation characteristic, but the switch connected in series could become another malfunction source. Moreover, once the switch is included, system ground malfunction detection becomes non-continuous, hence it still leaves a lot to be desired.

To overcome the drawbacks of unable to provide alert during ground malfunction of a non-grounding power supply system and unable to judge which power supply loop has ground malfunction, another improved conventional detection circuit is proposed as shown in FIG. 2. It comprises a plurality of breaker elements 2 at the positive and negative voltage terminals of a power supply system 1, a leakage current detector 3 at the distal end of the power supply system 1, a positive voltage transient compensator 4 at the positive voltage terminal and a negative voltage transient compensator 5 at the negative voltage terminal. The positive voltage transient compensator 4 and negative voltage transient compensator 5 have respectively a charge circuit 41 and 51, a storage circuit 42 and 52 and a discharge circuit 43 and 53. The charge circuits 41 and 51 include respectively a resistor 411 and 511 and a one-way charger 412 and 512 coupled in series. The charge circuits 41 and 51 respectively have one end connected to the positive voltage terminal of the power supply system 1 and another end connected in series to the storage circuit 42 and 52. The storage circuits 42 and 52 have respectively another end grounded. The storage circuits 42 and 52 include respectively a resistor 421 and 521 and a storage device 422 and 522 coupled in parallel. The discharge circuits 43 and 53 are coupled respectively with the charge circuits 41 and 51 in parallel, and include respectively a one-way discharger 431 and 531 and a resistor 432 and 532 coupled in series.

The leakage current detector 3 detects grounded leakage current generated by discharge of the storage voltage of the storage device 422 passing through the serial-connected insulation resistor R_{f} through the resistor 432 in the positive voltage transient compensator 4 (similar phenomenon also can take place in the negative voltage transient compensator 5, details are omitted herein). The leakage current detector 3 detects significant increase of current and issues alarm or controls the breaker elements 2 to stop power supply of the power supply system 1 to the loads, thereby achieve the purpose of detecting the ground malfunction.

The storages devices 422 and 522 of the storage circuits 42 and 52 can be capacitors. When the insulation resistor R_{f} is in good conditions the capacitors can save energy normally.

However, in the event that malfunction occurs to the insulation resistor R_{f} and the resistance drops drastically, the stored energy of the capacitors discharges to the ground terminal through the insulation resistor R_{f}. The grounded leakage current has a maximum value derived from the transient voltage value at the initial storage state divided by the resistance of the resistor 432 coupled with the insulation resistance R_{f} in series.

However, in practice the insulation resistance R_{f} usually does not drop drastically, but could deteriorate and attenuate gradually. Since the capacitors are passive electronic elements, they discharge slowly to the insulation resistor R_{f} during the change process thereof, hence the storage voltage of the capacitors also drops gradually. As a result, the leakage current detector 3, due to its limited precision, cannot accurately detect variations of the grounded leakage current and thereby fails to make precise detection. In short, the conventional insulation malfunction detection circuit has the drawback of unable to detect the malfunction mode caused by gradually deterioration and attenuation of the insulation resistor.

### SUMMARY OF THE INVENTION

The primary object of the present invention is to provide an insulation malfunction detection circuit that employs an active power source unit as drive power to allow a leakage current detector to successfully and continuously detect malfunction status of an insulation resistance during a slow deterioration and attenuation process.

To achieve the foregoing object, the insulation malfunction detection circuit according to the invention includes at least one leakage current detection unit located on one loop of a power supply system for detecting and measuring leakage current value of the loop, at least one positive voltage terminal compensation unit with one end connected to a positive voltage terminal of the power supply system and another end connected to a ground terminal and also having a first one-way discharger, a first resistor and a first power source unit that are coupled in series with the first one-way discharger and first power source unit being forward conducted, and at least one negative voltage terminal compensation unit with one end connected to a negative voltage terminal of the power supply system and another end connected to the ground terminal and also having a second one-way discharger, a second resistor and a second power source unit that are coupled in series with the second one-way discharger and second power source unit being forward conducted.

The invention provides improvement over the flaw of the conventional non-grounding DC power supply system which uses passive elements such as capacitors to detect ground insulation deterioration by providing a first power source unit in the positive voltage terminal compensation unit to discharge through the first one-way discharger in the event that ground insulation deterioration occurs to the positive voltage terminal at the power output side of the leakage current detection unit so that the leakage current is grounded with the positive voltage terminal compensation unit through the ground network to form a leakage current loop, thereby a small change of insulation resistance can be detected timely and the leakage current detection unit can detect variations of current passing through the positive voltage terminal and negative voltage terminal to issue alert signals or cut off breaker elements to suspend power supply to the loop. Thus high sensitive and continuous detection can be achieved, and instant online leakage current alert of each loop in the DC system during power supply operation also can be provided. Moreover, as the resistor coupled in series with the power source unit has a definite resistance, total grounded leakage current value of the power supply loop can be obtained via the voltage of the resistor for operation people without the need of installing other extra current detector. Similarly, in the event that ground insulation deterioration occurs to the negative voltage terminal circuit at the power output side of the leakage current detection unit, the leakage current flows to the ground terminal of the negative voltage terminal compensation unit to achieve the same monitoring purpose.

In short, the invention provides many advantages, notably:
1. Actively monitor and measure in an instant and continuous fashion.
2. Adoptable to different loops of a power supply system.
3. Can effectively detect the malfunction mode in slow deterioration and attenuation of a grounding insulation resistance.
4. Can simultaneously detect and measure leakage current values of loops.

The foregoing, as well as additional objects, features and advantages of the invention will be more readily apparent from the following detailed description, which proceeds with reference to the accompanying drawings.

### BRIEF DESCRIPTION OF THE DRAWINGS

FIG. 1 is a circuit diagram of a conventional detection circuit.

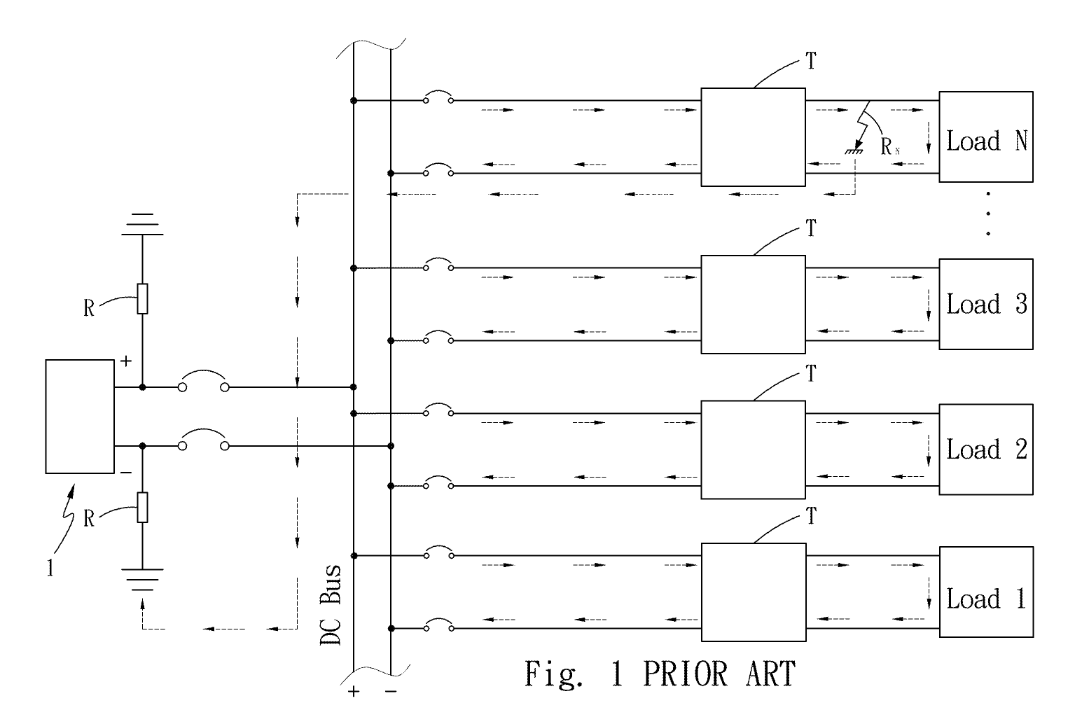

FIG. 2 is a circuit diagram of an improved conventional detection circuit.

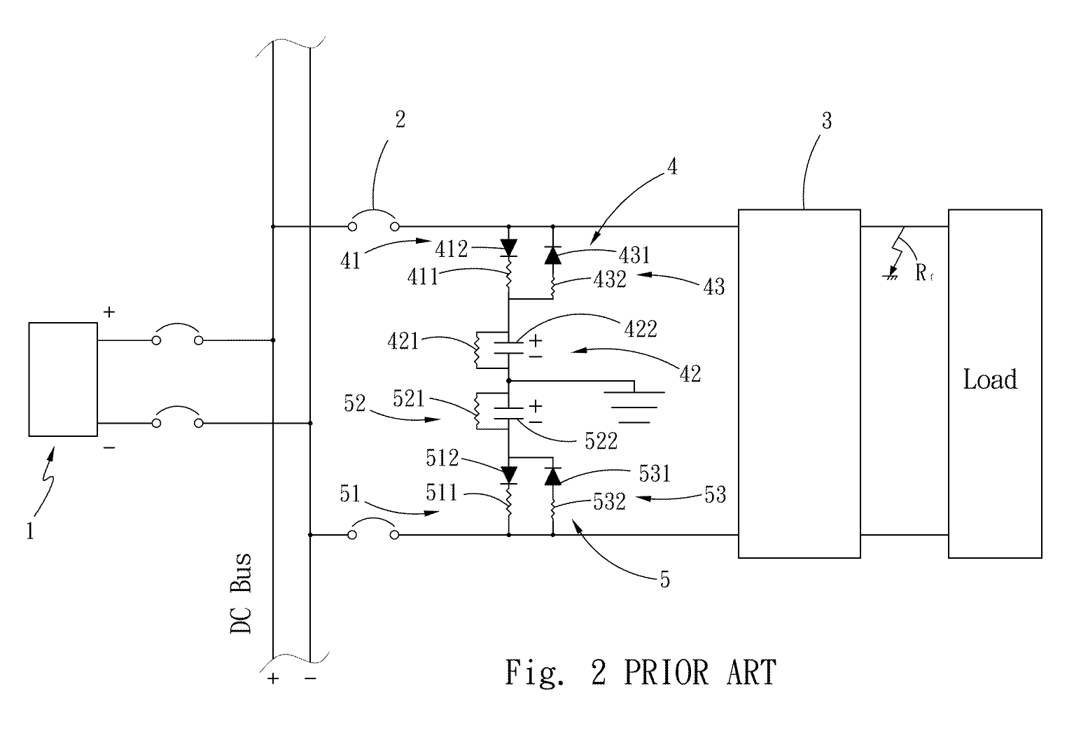

FIG. 3 is the main circuit diagram of the invention.

FIG. 4 is a schematic view of the invention located on varying loops and showing leakage current flowing directions.

FIG. 5 is a schematic view of the invention located on a DC bus and showing leakage current flowing directions.

FIG. 6 is a schematic view of the invention installed between a main power source and a DC bus and showing leakage current flowing directions.

FIG. 7 is a circuit diagram of the invention located on a single loop.

FIG. 8 is a schematic view of the invention installed on a main power source and showing leakage current flowing directions.

### DETAILED DESCRIPTION OF THE PREFERRED EMBODIMENTS

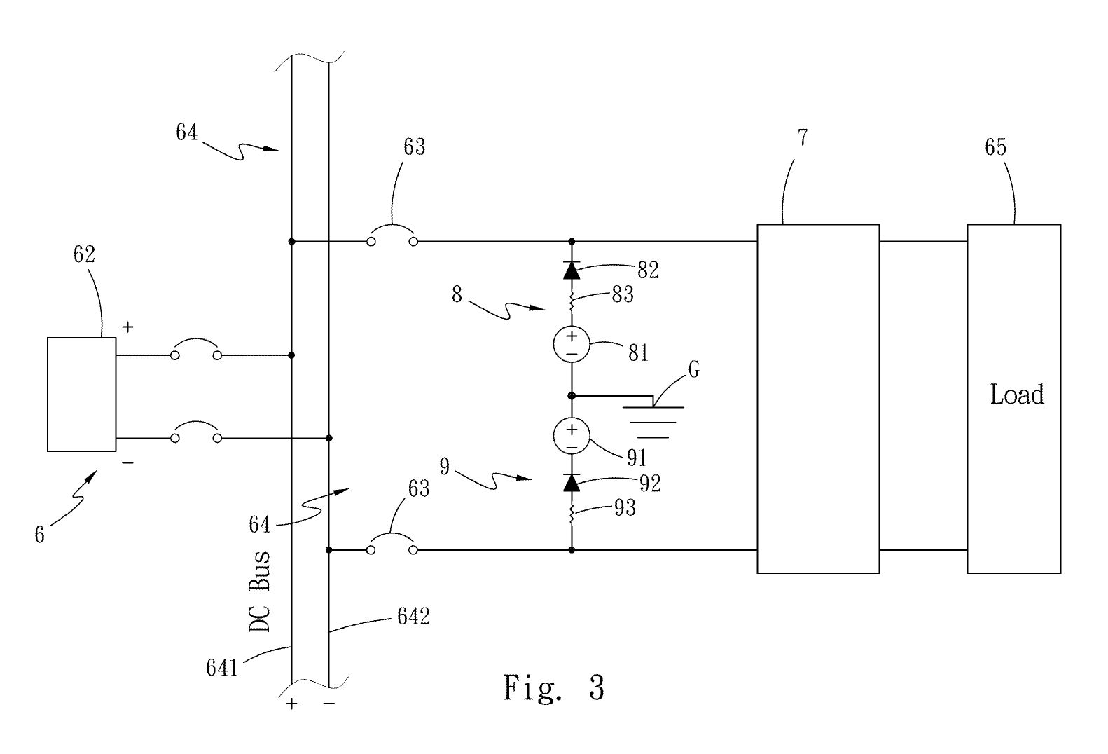

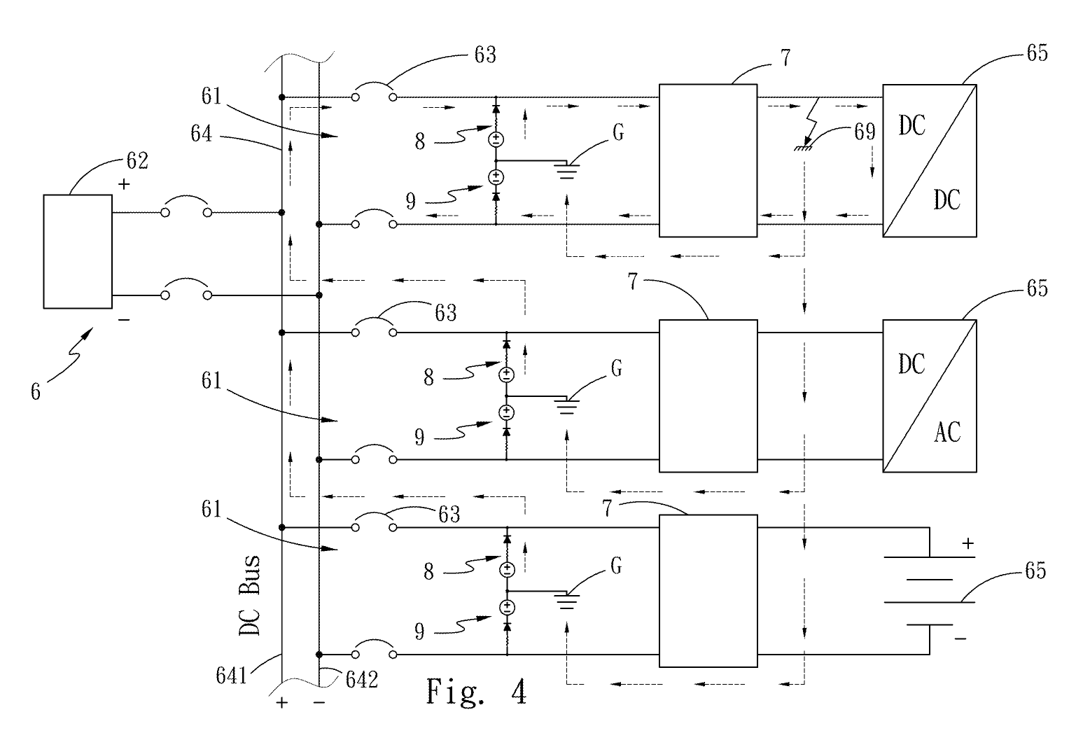

Please refer to FIGS. 3 and 4, the present invention aims to provide an active continuous DC power supply insulation malfunction detection circuit which comprises a plurality of breaker elements 63, a plurality of leakage current detection units 7, and a plurality of positive voltage terminal compensation units 8 and a plurality of negative voltage terminal compensation units 9.

The breaker elements 63 are respectively located at a positive voltage terminal 641 and a negative voltage terminal 642 of each loop 61 of a power supply system 6 for stopping power supply of the loop 61. The power supply system 6 includes a main power source 62 and a DC bus 64.

Each leakage current detection unit 7 is located on one loop 61 for detecting and measuring leakage current value of the loop 61 when being grounded. In the event that an abnormal grounded leakage current is detected, an alert signal is issued or the breaker elements 63 are controlled to cut off to stop power supply to the loop 61.

Each positive voltage terminal compensation unit 8 is installed on one loop 61 of the power supply system 6 and has one end connected to the positive voltage terminal 641 of the power supply system 6 and another end connected to a ground terminal G. The positive voltage terminal compensation unit 8 includes a first one-way discharger 82, a first resistor 83 and a first power source unit 81 that are coupled in series. The first one-way discharger 82 is a diode and forms forward conduction with the first power source unit 81. Each negative voltage terminal compensation unit 9 is installed on one loop 61 of the power supply system 6 and has one end connected to the negative voltage terminal 642 of the power supply system 6 and another end connected to the ground terminal G. The negative voltage terminal compensation unit 9 includes a second one-way discharger 92, a second resistor 93 and a second power source unit 91 that are coupled in series. The ground terminal G can be a motor vehicle chassis or ground network.

The power source units 81 and 91 of the positive voltage terminal compensation unit 8 and negative voltage terminal compensation unit 9 are respectively an additionally added DC power source separated from the main power source 62 and DC bus 64, and can be implemented in one of the following three embodiments:
1. A DC power source receives an input from an AC power source, and the input is converted by an isolation transformer, a rectifier and a filter; or
2. A DC power source receives an input from a main power source 62 and DC bus 64, and the input is converted by a DC/DC power converter having an isolation transformer; or
3. A DC power source receives an input directly from an independent battery.

When one of the three embodiments mentioned above is implemented, the total voltage of the power source units 81 and 91 is smaller than the total voltage of the main power source 62. For instance, when the main power source 62 is at voltage 120V, and the power source units 81 and 91 can be at 50V respectively. In a general normal use condition, the one-way dischargers 82 and 92 are forward conducted to be open circuit elements. In the event that ground insulation deterioration 69 takes place on the positive and negative power terminal at the power output side 65 of the leakage current detection unit 7, the one-way dischargers 82 and 92 are conducted, and the power source units 81 and 91 immediately discharge through the one-way dischargers 82 and 92.

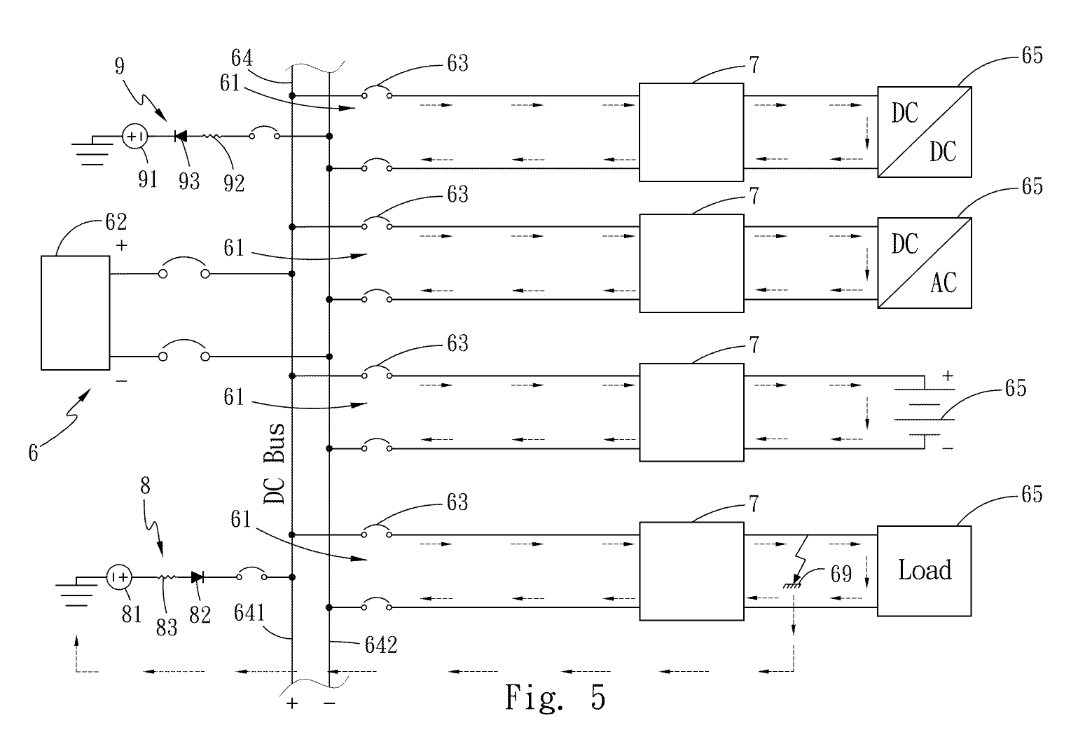

Please refer to FIGS. 5 through 8 for various embodiments of the invention. First, as shown in FIG. 5, a positive voltage terminal compensation unit 8 and a negative voltage terminal compensation unit 9 are located on the DC bus 64 to serve as a common route for leakage current of each loop 61 to allow the leakage current detection unit 7 to successfully detect and measure the leakage current (the flowing directions of the leakage current are indicated by the arrows).

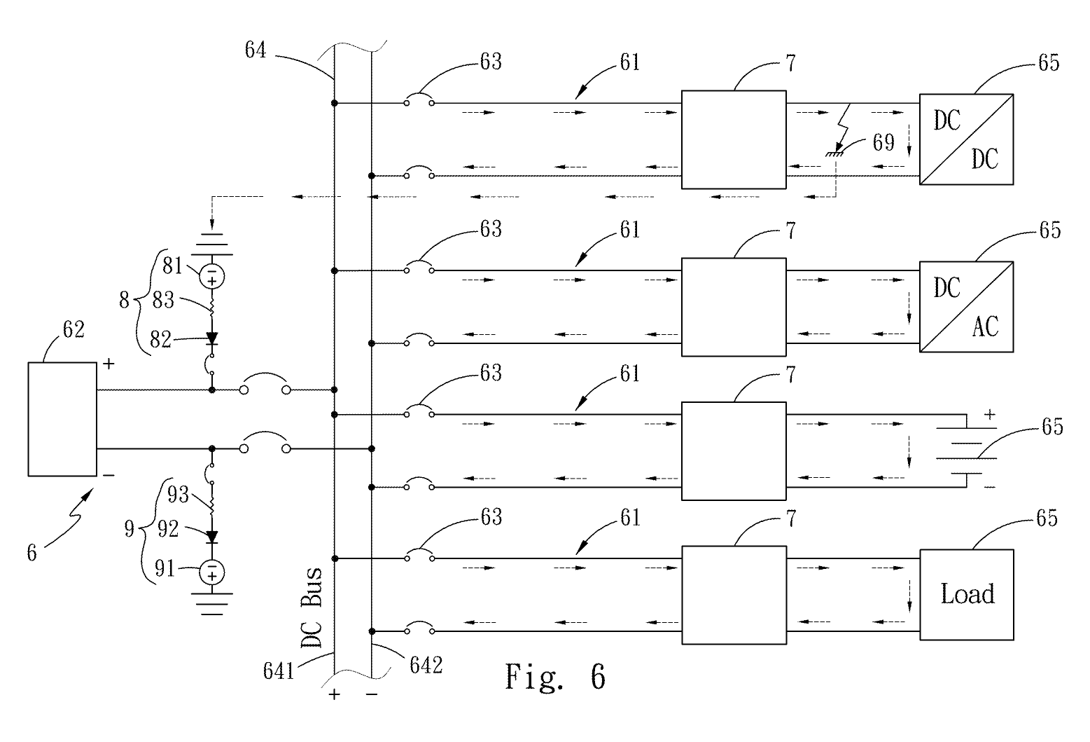

FIG. 6 illustrates another embodiment in which a positive voltage terminal compensation unit 8 and a negative voltage terminal compensation unit 9 are located between the main power source 62 and DC bus 64 of the power supply system 6. Such a structure also can provide a route for the leakage current.

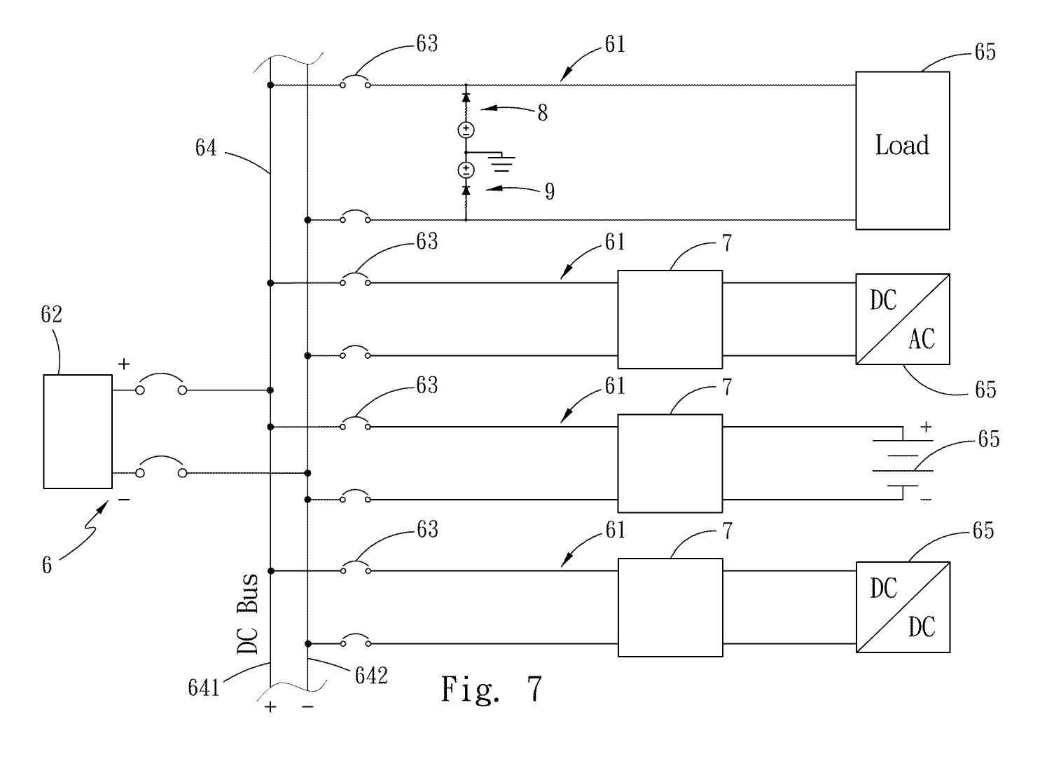

FIG. 7 illustrates yet another embodiment in which a positive voltage terminal compensation unit 8 and a negative voltage terminal compensation unit 9 are located on one loop 61 without installing a leakage current detection unit 7 to serve as a route for the leakage current. Other loops 61 equipped with the leakage current detection unit 7 still can provide leakage current monitoring and measuring function.

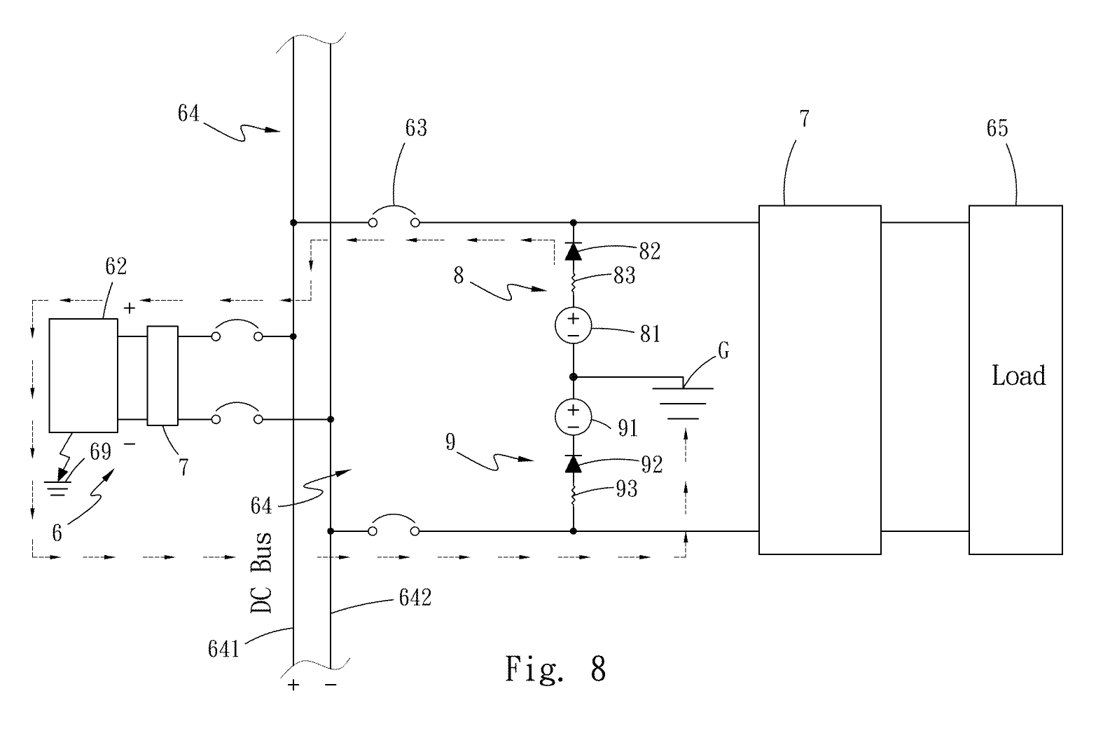

FIG. 8 illustrates yet another embodiment in which a positive voltage terminal compensation unit 8 is connected to a positive voltage terminal of the main power source 62 of the power supply system 6, and a negative voltage terminal compensation unit 9 is connected to a negative voltage terminal of the main power source 62, and the leakage current detection unit 7 is located at one side of the main power source 62. In the event that ground insulation resistor deterioration and attenuation occurs to the main power source 62, the leakage current detection unit 7 can immediately detect and measure the leakage current value of the main power source 62.

As a conclusion, the invention can be arbitrarily located at the positive voltage terminal 641 or negative voltage terminal 642 to monitor deterioration and attenuation of grounding insulation resistance. Through the power source units 81 and 91 respectively located in the positive and negative voltage terminal compensation units 8 and 9, the invention can provide an improvement over the shortcoming of the conventional detection circuit which can merely detect instantaneous drastic deterioration of the grounding insulation resistance. Moreover, the leakage current detection unit 7 can continuously monitor the insulation resistor in higher sensitivity without interruption and thus grounded leakage current values of the power supply loops can be provided for operation people.

What is claimed is:

1. An active continuous DC power supply insulation malfunction detection circuit, comprising:
at least one leakage current detection unit located on at least one loop of a power supply system for detecting and measuring leakage current value of the loop;
at least one positive voltage terminal compensation unit which includes one end connected to a positive voltage terminal of the power supply system and another end connected to a ground terminal, and a first one-way discharger, a first resistor and a first power source unit providing DC power that are coupled in series, the first one-way discharger and the first power source unit being forward conducted; and
at least one negative voltage terminal compensation unit which includes one end connected to a negative voltage terminal of the power supply system and another end connected to the ground terminal, and a second one-way discharger, a second resistor and a second power source unit providing DC power that are coupled in series, the second one-way discharger and the second power source unit being forward conducted.

2. The active continuous DC power supply insulation malfunction detection circuit of claim 1, wherein the power supply system further includes a DC bus connected to a main power source of the power supply system to form a plurality of loops, the DC bus including a plurality of positive voltage terminals and a plurality of negative voltage terminals.

3. The active continuous DC power supply insulation malfunction detection circuit of claim 1, wherein the positive voltage terminal compensation unit and the negative voltage terminal compensation unit are located on the loop of the power supply system.

4. The active continuous DC power supply insulation malfunction detection circuit of claim 1, wherein the positive voltage terminal compensation unit is located at the positive voltage terminal of a main power source of the power supply system, and the negative voltage terminal compensation unit is located at the negative voltage terminal of the main power source of the power supply system.

5. The active continuous DC power supply insulation malfunction detection circuit of claim 1, wherein the leakage current detection unit is located at a main power source of the power supply system for detecting and measuring leakage current value of the main power source.

6. The active continuous DC power supply insulation malfunction detection circuit of claim 1, wherein the first and second power source units are DC power sources of converting AC power to DC power or converting DC power to DC power, or batteries.

7. The active continuous DC power supply insulation malfunction detection circuit of claim 1, wherein the ground terminal is a ground network.
